(19) United States
(12) Patent Application Publication
(10) Pub. No.: US 2012/0152352 A1
(43) Pub. Date: Jun. 21, 2012

(54) PHOTOVOLTAIC DEVICES WITH AN INTERFACIAL GERMANIUM-CONTAINING LAYER AND METHODS FOR FORMING THE SAME

(75) Inventors: Tze-Chiang Chen, Yorktown Heights, NY (US); Jee H. Kim, Los Angeles, CA (US); Devendra K. Sadana, Pleasantville, NY (US); Ahmed Abou-Kandil, Elmsford, NY (US); Mohamed Saad, White Plains, NY (US)

(73) Assignees: EGYPT NANOTECHNOLOGY CENTER, Cairo-Alexandria (EG); INTERNATIONAL BUSINESS MACHINES CORPORATION, Armonk, NY (US)

(21) Appl. No.: 12/968,490

(22) Filed: Dec. 15, 2010

(51) Int. Cl. H01L 31/0264; H01L 31/18

(52) U.S. Cl. 136/261; 438/69; 257/E31.001

(57) ABSTRACT

A germanium-containing layer is provided between a p-doped silicon-containing layer and a transparent conductive material layer of a photovoltaic device. The germanium-containing layer can be a p-doped silicon-germanium alloy layer or a germanium layer. The germanium-containing layer has a greater atomic concentration of germanium than the p-doped silicon-containing layer. The presence of the germanium-containing layer has the effect of reducing the series resistance and increasing the shunt resistance of the photovoltaic device, thereby increasing the fill factor and the efficiency of the photovoltaic device. In case a silicon-germanium alloy layer is employed, the closed circuit current density also increases.

### BACKGROUND

The present disclosure relates to photovoltaic devices, and more particularly to photovoltaic devices including an interfacial germanium-containing layer and methods of forming the same.

A photovoltaic device is a device that converts the energy of incident photons to electromotive force (e.m.f.). Typical photovoltaic devices include solar cells, which are configured to convert the energy in the electromagnetic radiation from the Sun to electric energy. Each photon has an energy given by the formula E=hν, in which the energy E is equal to the product of the Plank constant h and the frequency ν of the electromagnetic radiation associated with the photon.

A photon having energy greater than the electron binding energy of a matter can interact with the matter and free an electron from the matter. While the probability of interaction of each photon with each atom is probabilistic, a structure can be built with a sufficient thickness to cause interaction of photons with the structure with high probability. When an electron is knocked off an atom by a photon, the energy of the photon is converted to electrostatic energy and kinetic energy of the electron, the atom, and/or the crystal lattice including the atom. The electron does not need to have sufficient energy to escape the ionized atom. In the case of a material having a band structure, the electron can merely make a transition to a different band in order to absorb the energy from the photon.

The positive charge of the ionized atom can remain localized on the ionized atom, or can be shared in the lattice including the atom. When the positive charge is shared by the entire lattice, thereby becoming a non-localized charge, this charge is described as a hole in a valence band of the lattice including the atom. Likewise, the electron can be non-localized and shared by all atoms in the lattice. This situation occurs in a semiconductor material, and is referred to as photogeneration of an electron-hole pair. The formation of electron-hole pairs and the efficiency of photogeneration depend on the band structure of the irradiated material and the energy of the photon. In case the irradiated material is a semiconductor material, photogeneration occurs when the energy of a photon exceeds the band gap energy, i.e., the energy difference of a band gap of the irradiated material.

The direction of travel of charged particles, i.e., the electrons and holes, in an irradiated material is sufficiently random. Thus, in the absence of any electrical bias, photogeneration of electron-hole pairs merely results in heating of the irradiated material. However, an external field can break the spatial direction of the travel of the charged particles to harness the electrons and holes formed by photogeneration.

One exemplary method of providing an electric field is to form a p-i-n junction around the irradiated material. As negative charges accumulate in the p-doped region and positive charges accumulate in the n-doped region, an electric field is generated from the direction of the n-doped region toward the p-doped region. Electrons generated in the intrinsic region drift towards the n-doped region due to the electric field, and holes generated in the intrinsic region drift towards the p-doped region. Thus, the electron-hole pairs are collected systematically to provide positive charges at the p-doped region and negative charges at the n-doped region. The p-i-n junction forms the core of this type of photovoltaic device, which provides electromotive force that can power any device connected to the positive node at the p-doped region and the negative node at the n-doped region.

### BRIEF SUMMARY

A germanium-containing layer is provided between a p-doped silicon-containing layer and a transparent conductive material layer of a photovoltaic device. The germanium-containing layer can be a silicon-germanium alloy layer or a germanium layer. The germanium-containing layer has a greater atomic concentration of germanium than the p-doped silicon-containing layer. The presence of the germanium-containing layer has the effect of reducing the series resistance and increasing the shunt resistance of the photovoltaic device, thereby increasing the fill factor and the efficiency of the photovoltaic device.

According to an aspect of the present disclosure, a photovoltaic device is provided, which includes a stack of a transparent conductive material layer, a germanium-containing layer contacting the transparent conductive material layer, and a p-doped silicon-containing layer contacting the p-doped silicon-containing layer. The germanium-containing layer has a greater atomic concentration of germanium than the p-doped silicon-containing layer. The photovoltaic device provides a greater shunt resistance and a lesser series resistance than a photovoltaic device having a same material stack less a germanium-containing layer.

According to another aspect of the present disclosure, a method of forming a photovoltaic device is provided. The method includes: forming a transparent conductive material layer on a substrate; forming a germanium-containing layer on the transparent conductive material layer; and forming a p-doped silicon-containing layer on the germanium-containing layer. The photovoltaic device provides a greater shunt resistance and a lesser series resistance than a photovoltaic device having a same material stack less a germanium-containing layer.

### BRIEF DESCRIPTION OF THE SEVERAL VIEWS OF THE DRAWINGS

FIG. 1 is a vertical cross-sectional view of a prior art photovoltaic device structure.

FIG. 2 is an equivalent circuit for the prior art photovoltaic device structure of FIG. 1.

FIG. 3 is a schematic graph of an I-V curve of the prior art photovoltaic device structure of FIG. 1.

FIG. 4 is a band diagram of a transparent conductive material layer and a p-doped silicon-containing layer in the prior art photovoltaic device structure of FIG. 1.

FIG. 5 is a graph of an I-V curve for an exemplary prior art photovoltaic device structure.

FIG. 6 is a vertical cross-sectional view of an exemplary photovoltaic device structure according to an embodiment of the present disclosure.

FIG. 7 is a schematic graph of an J-V curves of an exemplary photovoltaic device of FIG. 6 and a prior art photovoltaic device structure of FIG. 1.

FIG. 8A is a vertical cross-sectional view of an exemplary photovoltaic device structure after formation of a transparent conductive material layer according to an embodiment of the present disclosure.

FIG. 8B is a vertical cross-sectional view of an exemplary photovoltaic device structure after formation of a germanium-containing layer according to an embodiment of the present disclosure.

FIG. 8C is a vertical cross-sectional view of an exemplary photovoltaic device structure after formation of back reflector layers according to an embodiment of the present disclosure.

### DETAILED DESCRIPTION

As stated above, the present disclosure relates to photovoltaic devices including an interfacial germanium-containing layer and methods of forming the same, which are now described in detail with accompanying figures. Throughout the drawings, the same reference numerals or letters are used to designate like or equivalent elements. The drawings are not necessarily drawn to scale.

As used herein, a crystal structure is “microcrystalline” if the average grain size of the material is from 1 nm to 10 microns.

As used herein, a “hydrogenated” semiconductor material is a semiconductor material including incorporated hydrogen therein, which neutralizes dangling bonds in the semiconductor material and allows charge carriers to flow more freely.

As used herein, a “semiconductor-material-containing reactant gas” refers to a gas including at least one atom of Si, Ge, or components of a compound semiconductor material.

As used herein, an element is “optically transparent” if the element is transparent in the visible electromagnetic spectral range having a wavelength from 400 nm to 800 nm.

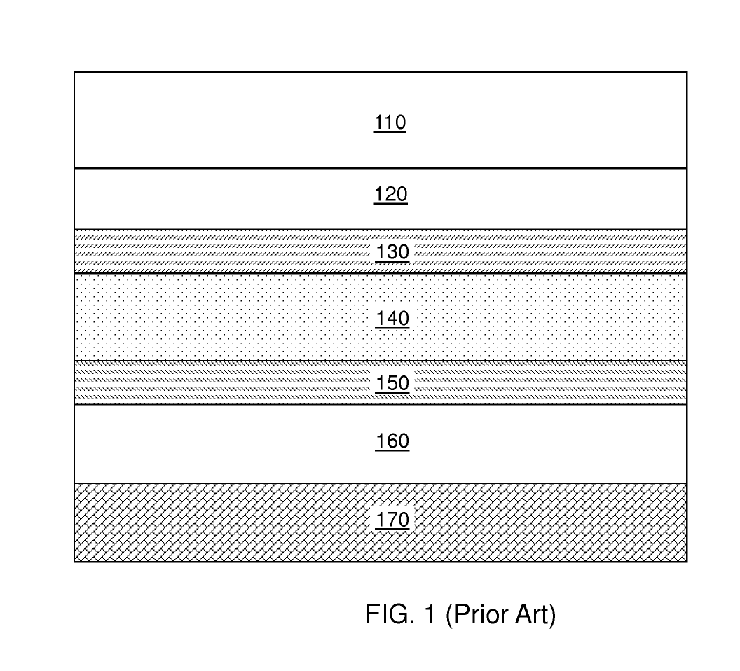

Referring to FIG. 1, a prior art photovoltaic device structure includes a material stack, from top to bottom, of a substrate 110, a transparent conductive material layer 120, a p-doped silicon-containing layer 130, an intrinsic semiconductor layer 140, an n-doped semiconductor layer 150, a first back reflector layer 160, and a second back reflector layer 170. The substrate 110 typically includes an optically transparent material. The transparent conductive material layer 120 functions as a positive node of the prior art photovoltaic device, and the combination of the second back reflector layer 170 functions as a negative node of the prior art photovoltaic device. The first back reflector layer 160 can be optically transparent, and the combination of the first and second back reflector layers (160, 170) reflect any photons that pass through the stack of the p-doped silicon-containing layer 130, the intrinsic semiconductor layer 140, and the n-doped semiconductor layer 150 to enhance the efficiency of the prior art photovoltaic device.

The p-doped silicon-containing layer 130 can include an amorphous p-doped hydrogenated silicon-containing material or microcrystalline p-doped hydrogenated silicon-containing material. The amorphous p-doped hydrogenated silicon-containing material or the microcrystalline p-doped hydrogenated silicon-containing material can be deposited by flowing a semiconductor-material-containing reactant in a hydrogen carrier gas. In this case, hydrogen atoms are incorporated in the deposited material of the p-doped silicon-containing layer 130. The p-doped silicon-containing layer 130 can include an amorphous p-doped hydrogenated silicon-carbon alloy or a microcrystalline p-doped hydrogenated silicon-carbon alloy.

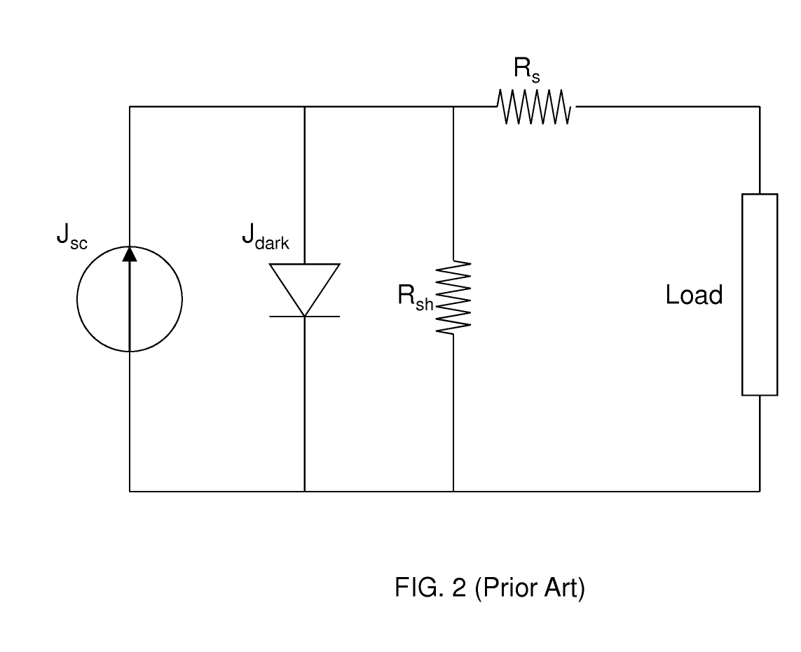

Referring to FIG. 2, the functionality of the prior art photovoltaic device of FIG. 1 can be approximated by an equivalent circuit that includes a current source, a diode, and two resistors. The equivalent circuit of FIG. 2 approximates a unit area of the prior art photovoltaic device of FIG. 1, which provides electrical current that is proportional to the total irradiated area of the prior art photovoltaic device. The photovoltaic current per unit area generated by the prior art photovoltaic device is referred to as a short-circuit current density J_{sc}, i.e., the current density generated by the prior art photovoltaic device if the positive node and the negative node of the prior art photovoltaic device are electrically shorted. Thus, the current source in FIG. 2 generates an electrical current with a current density of the short-circuit current density J_{sc}.

Power dissipation through internal leakage current is approximated by a shunt resistance Rₛₕ. A finite value for the shunt resistance Rₛₕ triggers an internal leakage current through the prior art photovoltaic device of FIG. 1, and degrades the performance of the prior art photovoltaic device. The lesser the shunt resistance Rₛₕ, the greater is the internal power loss due to the internal leakage current.

Power dissipation through internal resistance of the prior art photovoltaic device of FIG. 1 is approximated by a series resistance Rₛ. A non-zero value for the series resistance Rₛ triggers Joule loss within the prior art photovoltaic device. The greater the series resistance Rₛ, the greater is the internal power loss due to the internal resistance of the prior art photovoltaic device.

The potential difference between the positive node, i.e., the p-doped silicon-containing layer 130, and the negative node, i.e., the n-doped semiconductor layer 150, generates an internal current that flow in the opposite direction to the photocurrent, i.e., the current represented by the current source having the short-circuit current density J_{sc}. The dark current has the same functional dependence on the voltage across the current source as a diode current. Thus, the dark current is approximated by a diode that allows a reverse-direction current. The density of the dark current, i.e., the dark current per unit area of the prior art photovoltaic device, is referred to as the dark current density J_{dark}. An external load can be attached to an outer node of the series resistor and one of the nodes of the current source. In FIG. 2, the value the impedance of the load is the value of the actual impedance of a physical load is divided by the area of the prior art photovoltaic cell because the equivalent circuit of FIG. 2 describes the functionality of a unit area of the prior art photovoltaic cell.

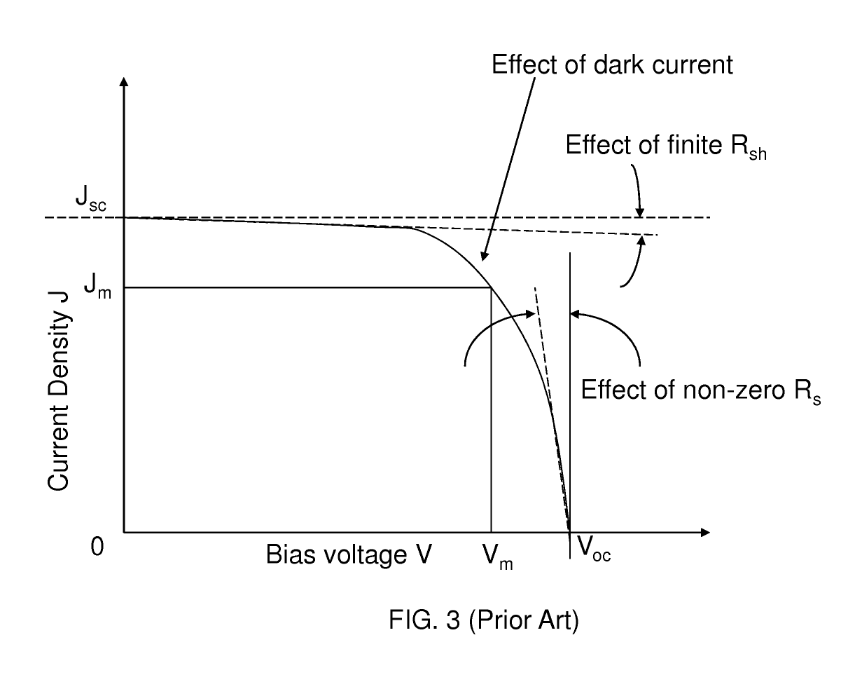

Referring to FIG. 3, a schematic graph of an I-V curve of the prior art photovoltaic device structure of FIG. 1 is shown. The bias voltage V is the voltage across the load in the equivalent circuit of FIG. 2. The open circuit voltage Voc corresponds to the voltage across the load as the resistance of the load diverges to infinity, i.e., the voltage across the current source when the load is disconnected. The inverse of the absolute value of the slope of the I-V curve at V=0 and J=J_{sc} is approximately equal to the value of the shunt resistance Rₛₕ. The inverse of the absolute value of the slope of the I-V curve at V=V_{oc} and J=0 is approximately equal to the value of the series resistance Rₛ. The effect of the dark current is shown as an exponential decrease in the current density J as a function of the bias voltage V around a non-zero value of the bias voltage.

The operating range of a photovoltaic device is the portion of the I-V curve in the first quadrant, i.e., when both the bias voltage V and the current density J are positive. The power density P, i.e., the density of power generated from an unit area of the prior art photovoltaic device of FIG. 1, is proportional to the product of the voltage V and the current density J along the I-V curve. The power density P reaches a maximum at a maximum power point of the I-V curve, which has the bias voltage of Vₘ and the current density of Jₘ. The fill factor FF is defined by the following formula:

$$F F = \frac{{J}_{m} \times {V}_{m}}{{J}_{sc} \times {V}_{oc}} . \qquad ( Eq . 1 )$$

The fill factor FF defines the degree by which the I-V curve of FIG. 3 approximates a rectangle. The fill factor FF is affected by the series resistance Rₛ and the shunt resistance Rₛₕ. The smaller the series resistance Rₛ, the greater the fill factor FF. The greater the shunt resistance Rₛₕ, the greater the fill factor FF. The theoretical maximum for the fill factor is 1.0.

The efficiency η of a photovoltaic device is the ratio of the power density at the maximum power point to the incident light power density Pₛ. In other words, the efficiency η is given by:

$$η = \frac{{J}_{m} \times {V}_{m}}{{P}_{s}} . \qquad ( Eq . 2 )$$

Eq. 2 can be rewritten as:

$$η = \frac{{J}_{sc} \times {V}_{oc} \times F F}{{P}_{s}} . \qquad ( Eq . 3 )$$

Thus, the efficiency h of a photovoltaic device is proportional to the short circuit current density J_{sc}, the open circuit voltage V_{oc}, and the fill factor FF.

The efficiency η of a photovoltaic device depends on the spectral composition of the incident light. For solar cells, the efficiency is calculated under a standard radiation condition defined as 1 sun, which employs the spectrum of the sunlight.

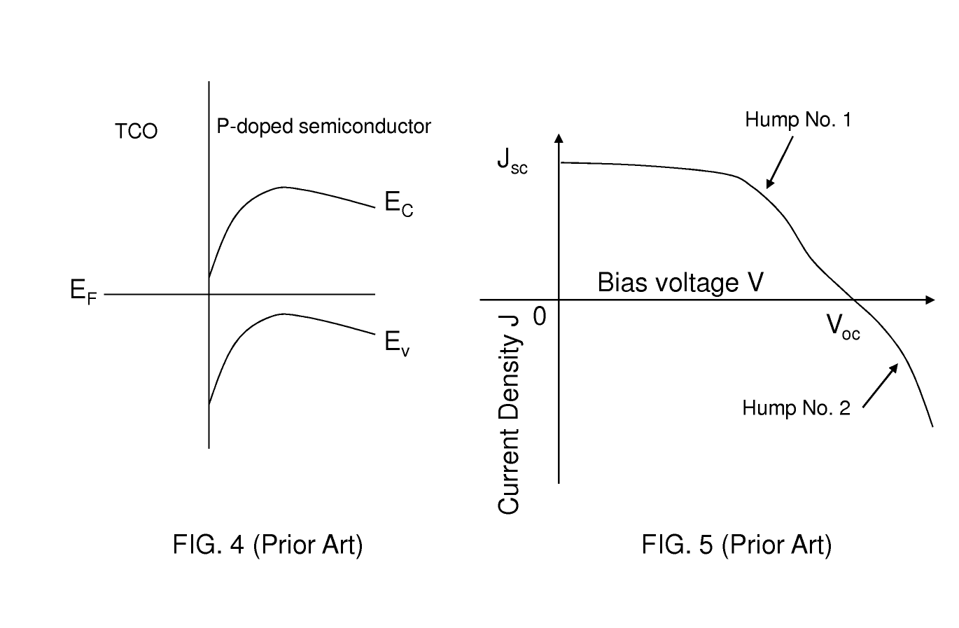

Referring to FIG. 4, a band diagram illustrates the band bending in the p-doped silicon-containing layer 130 in the prior art photovoltaic device structure of FIG. 1 due to the transparent conductive material layer 120. Materials currently available for the transparent conductive material layer 120 are n-type materials. The valence band and the conduction band of the p-doped silicon-containing layer 130 bend downward at the interface between the transparent conductive material layer 120 and the p-doped silicon-containing layer 130.

In case the transparent conductive material layer 120 is an aluminum-doped zinc oxide, the work function of the transparent conductive material layer 120 is about 4.5 eV. In other words, the Fermi level E_{F} is at 4.5 eV below the vacuum level. Other typical materials for the transparent conductive material layer 120 also have a work function of about 4.5 eV.

In case the p-doped silicon-containing layer 130 includes an amorphous hydrogenated silicon carbon alloy, the band gap of the p-doped silicon-containing layer 130 is around 1.85 eV. Since electron affinity of silicon is around 4 eV, the valence band edge of silicon is located around 5.85 eV below the vacuum level. The difference between the Fermi level and the valence band of the amorphous hydrogenated silicon carbon alloy is about 1.0 eV. This is a significant energy barrier, and is the cause of the predominant component of the series resistance Rₛ from 20 Ohms-cm² to 30 Ohms-cm² in the prior art photovoltaic device of FIG. 1.

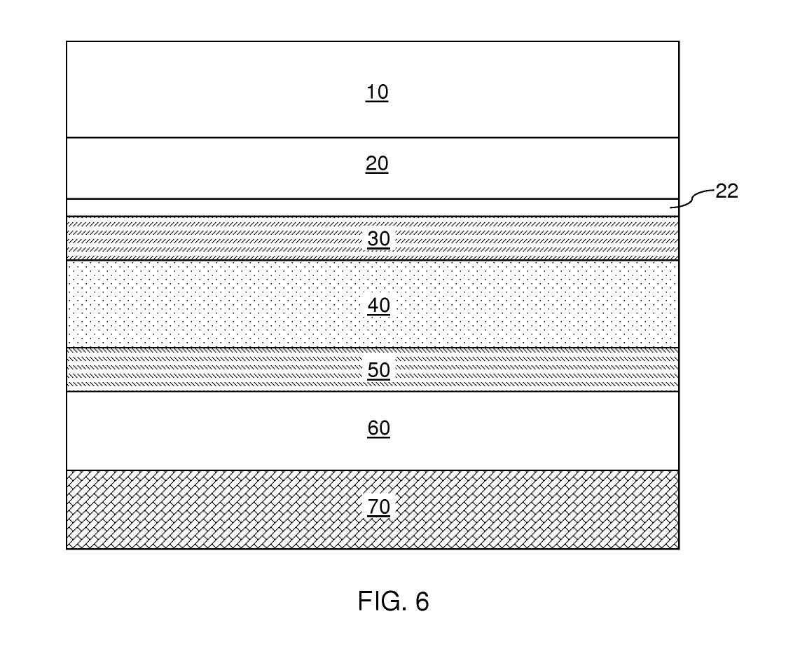

Referring to FIG. 5, the significant series resistance Rₛ in the prior art photovoltaic device of FIG. 1 can be manifested as humps in an I-V curve in case the p-doped silicon-containing layer 130 includes an amorphous hydrogenated silicon carbon alloy. The portion of the I-V curve in the fourth quadrant can be obtained by applying an external voltage across the positive and negative terminals of the prior art photovoltaic device of FIG. 1. The hump in the first quadrant can adversely affect the fill factor FF, and consequently affect the efficiency r adversely.

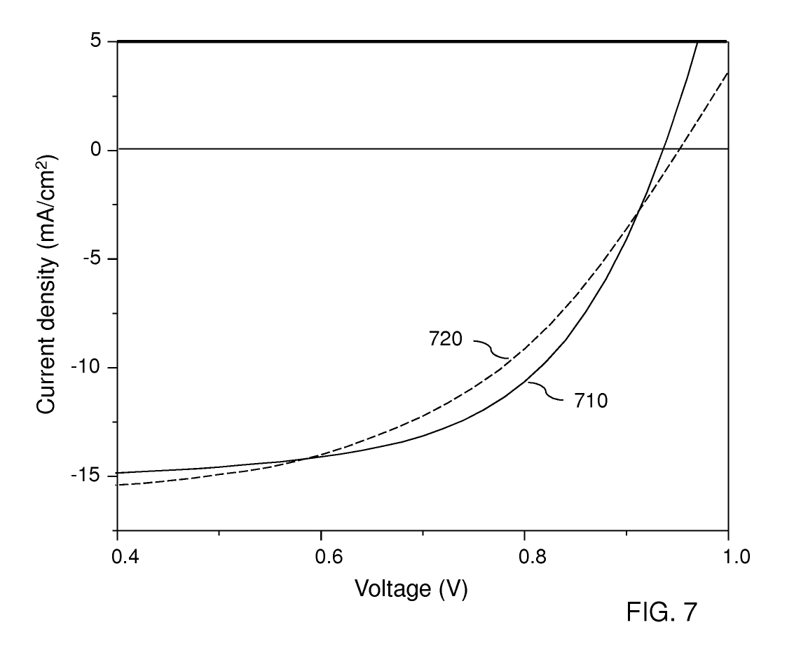

FIG. 6 is a vertical cross-sectional view of an exemplary photovoltaic device structure according to an embodiment of the present disclosure. The photovoltaic device structure includes a material stack, from top to bottom, of a substrate 10, a transparent conductive material layer 20, a germanium-containing layer 22, a p-doped silicon-containing layer 30, an intrinsic semiconductor layer 40, an n-doped semiconductor layer 50, a first back reflector layer 60, and a second back reflector layer 70.

The substrate 10 is a structure that provides mechanical support to the photovoltaic structure. The substrate 10 is transparent in the range of electromagnetic radiation at which photogeneration of electrons and holes occur within the photovoltaic structure. If the prior art photovoltaic device is a solar cell, the substrate 10 can be optically transparent. The substrate 10 can be a glass substrate. The thickness of the substrate 10 can be from 50 microns to 3 mm, although lesser and greater thicknesses can also be employed.

The transparent conductive material layer 20 includes a material that is transparent in the range of electromagnetic radiation at which photogeneration of electrons and holes occur within the photovoltaic device structure. If the photovoltaic device structure is employed as a solar cell, the transparent conductive material layer 20 can be optically transparent. For example, the transparent conductive material layer 20 can include a transparent conductive oxide such as a fluorine-doped tin oxide (SnO₂:F), an aluminum-doped zinc oxide (ZnO:Al), or indium tin oxide. The thickness of the transparent conductive material layer 20 can be from 300 nm to 3 microns, although lesser and greater thicknesses can also be employed.

The germanium-containing layer 22 includes germanium itself or at least one p-type dopant such as B, Ga, and In. The germanium-containing layer 22 may, or may not, include another semiconductor material such as silicon. In one embodiment, the germanium-containing layer 22 is a silicon-germanium alloy layer including germanium, silicon, optionally p-type dopant, and hydrogen. In this embodiment, the atomic concentration of germanium is greater than 50%. Depending on the work-function of TCO, Si content in Ge can be varied. The germanium-containing layer 22 has a greater atomic concentration of germanium than the p-doped silicon-containing layer 30, which may, or may not, include germanium. In another embodiment, the germanium-containing layer 22 is a germanium layer consisting of germanium, at optionally p-type dopant, and hydrogen.

The germanium-containing layer 22 can be amorphous, microcrystalline, or single crystalline. The germanium-containing layer 22 can include a hydrogenated material. For example, if the germanium-containing layer 22 includes a hydrogenated amorphous silicon-germanium alloy, a hydrogenated microcrystalline silicon-germanium alloy, a hydrogenated amorphous germanium, or a hydrogenated microcrystalline germanium, the hydrogenation of the material of the germanium-containing layer 22 decreases localized electronic states and increases the conductivity of the germanium-containing layer 22.

The germanium-containing layer 22 can be formed, for example, by plasma enhanced chemical vapor deposition (PECVD). The thickness of the germanium-containing layer 22 can be from 1 nm to 20 nm, and typically from 2 nm to 5 nm, although lesser and greater thicknesses can also be employed.

The p-doped silicon-containing layer 30 includes an amorphous, microcrystalline, or single-crystalline p-doped silicon-containing material. The p-doped silicon-containing layer 30 can be a p-doped silicon layer consisting of silicon and at least one p-type dopant and optionally hydrogen, a p-doped silicon-germanium alloy layer consisting of silicon, germanium, at least one p-type dopant and optionally hydrogen, a p-doped silicon-carbon alloy layer consisting of silicon, carbon, at least one p-type dopant and optionally hydrogen, or a p-doped silicon-germanium-carbon alloy layer consisting of silicon, germanium, carbon, at least one p-type dopant and optionally hydrogen.

In some cases, the p-doped silicon-containing layer 30 can include a hydrogenated amorphous, microcrystalline, or single-crystalline p-doped silicon-containing material. The presence of hydrogen in the p-doped silicon-containing layer 30 can increase the concentration of free charge carriers, i.e., holes, by delocalizing the electrical charges that are pinned to defect sites. The p-doped silicon-containing layer 30 can include amorphous, microcrystalline, or single crystalline p-doped silicon or an amorphous, microcrystalline, or single crystalline p-doped silicon-germanium alloy. In case the p-doped silicon-containing layer 30 includes germanium, the atomic concentration of germanium in the p-doped silicon-containing layer 30 is less than the atomic concentration of germanium in the germanium-containing layer 22.

A hydrogenated p-doped silicon-containing material can be deposited in a process chamber containing a silicon-containing reactant gas a carrier gas. To facilitate incorporation of hydrogen in the hydrogenated p-doped silicon-containing material, a carrier gas including hydrogen can be employed. Hydrogen atoms in the hydrogen gas within the carrier gas are incorporated into the deposited material to form an amorphous or microcrystalline hydrogenated p-doped silicon-containing material of the p-doped silicon-containing layer 30. The thickness of the p-doped silicon-containing layer 30 can be from 3 nm to 30 nm, although lesser and greater thicknesses can also be employed.

In one embodiment, the p-doped hydrogenated silicon-containing material can be an amorphous, microcrystalline, or single-crystalline p-doped hydrogenated silicon-carbon alloy. The atomic concentration of carbon in the p-doped hydrogenated silicon-carbon alloy of the p-doped silicon-containing layer 30 can be from 1% to 90%, and preferably from 1% to 10%. In this case, the band gap of the p-doped silicon-containing layer 30 can be from 1.85 eV to 2.5 eV.

The intrinsic semiconductor layer 40 includes an intrinsic hydrogenated semiconductor-containing material. The intrinsic hydrogenated semiconductor-containing material is deposited in a process chamber containing a semiconductor-material-containing reactant gas and a carrier gas including hydrogen. Hydrogen atoms in the hydrogen gas within the carrier gas are incorporated into the deposited material to form the intrinsic hydrogenated semiconductor-containing material of the intrinsic semiconductor layer 40. The intrinsic hydrogenated semiconductor-containing material can be amorphous or microcrystalline. Typically, the intrinsic hydrogenated semiconductor-containing material is amorphous. The thickness of the intrinsic semiconductor layer 40 depends on the diffusion length of electrons and holes in the intrinsic hydrogenated semiconductor-containing material. Typically, the thickness of the intrinsic semiconductor layer 40 is from 100 nm to 1 micron, although lesser and greater thicknesses can also be employed.

The intrinsic semiconductor layer 40 can include a silicon-containing material, a germanium-containing material, or a compound semiconductor material. In one embodiment, the intrinsic semiconductor layer 40 includes a silicon-containing material. The semiconductor material of the intrinsic semiconductor layer 40 can be amorphous intrinsic silicon.

The n-doped semiconductor layer 50 includes an n-doped semiconductor-containing material. The n-doped semiconductor layer 50 can be a hydrogenated material, in which case an n-doped hydrogenated semiconductor-containing material is deposited in a process chamber containing a semiconductor-material-containing reactant gas a carrier gas including hydrogen. The n-type dopants in the n-doped semiconductor layer 50 can be introduced by in-situ doping. Alternately, the n-type dopants in the n-doped semiconductor layer 50 can be introduced by subsequent introduction of dopants employing any method known in the art. The n-doped semiconductor layer 50 can be amorphous or microcrystalline. The thickness of the n-doped semiconductor layer 50 can be from 6 nm to 60 nm, although lesser and greater thicknesses can also be employed.

The n-doped semiconductor layer 50 can include a silicon-containing material, a germanium-containing material, or a compound semiconductor material. In one embodiment, the n-doped semiconductor layer 50 includes a silicon-containing material. The semiconductor material of the n-doped semiconductor layer 50 can be amorphous n-doped silicon.

The first back reflector layer 60 includes a transparent conductive material that is transparent in the range of electromagnetic radiation at which photogeneration of electrons and holes occur within the photovoltaic device structure. If the photovoltaic device structure is employed as a solar cell, the first back reflector layer 60 can be optically transparent. For example, the first back reflector layer 60 can include a transparent conductive oxide such as a fluorine-doped tin oxide (SnO₂:F), an aluminum-doped zinc oxide (ZnO:Al), or indium tin oxide. Since such transparent conductive oxide materials are n-type materials, the contact between the first back reflector layer 60 and the n-doped semiconductor layer 50 is Ohmic, and as such, the contact resistance between the first back reflector layer 60 and the n-doped semiconductor layer 50 is negligible. The thickness of the back reflector layer 60 can be from 25 nm to 250 nm, although lesser and greater thicknesses can also be employed.

The second back reflector layer 70 includes a metallic material. Preferably, the metallic material has a high reflectivity in the range of electromagnetic radiation at which photogeneration of electrons and holes occur within the photovoltaic device structure. The metallic material can include silver, aluminum, or an alloy thereof. The thickness of the second back reflector layer 70 can be from 100 nm to 1 micron, although lesser and greater thicknesses can also be employed.

The exemplary photovoltaic device structure of FIG. 6 provides enhanced performance over prior art photovoltaic device structure of FIG. 1 in terms of shunt resistance and series resistance. Table 1 below compares various performance metrics among samples of the exemplary photovoltaic device structure of FIG. 6 and samples of some prior art photovoltaic device structure of FIG. 1. In all samples, hydrogenated p-doped amorphous silicon is employed for a p-doped silicon-containing layer.

TABLE 1
Comparison of performance metrics of sample photovoltaic devices

| | | | | Short | | | |
|---|---|---|---|---|---|---|---|
| | Photovoltaic | | | Circuit | Open | | Efficiency |
| | Device | Shunt | Series | Current | Circuit | Fill | of the |
| Sample | Structure | Resistance | Resistance | Density | Voltage | Factor | device |
| No. | Type | (Ω-cm²) | (Ω-cm²) | (mA/cm²) | (mV) | (%) | (%) |
| 1 | Type shown | 880.0 | 23.8 | 14.4 | 961 | 47.0 | 6.5 |
| | in FIG. 1 | | | | | | |
| 2 | Type shown | 805.2 | 9.9 | 15.5 | 970 | 56.5 | 8.5 |
| | in FIG. 1 | | | | | | |
| 3 | Type shown | 880.0 | 9.2 | 14.6 | 960 | 58.0 | 7.3 |
| | in FIG. 1 | | | | | | |
| 4 | Type shown | 1,423.4 | 6.1 | 15.0 | 931 | 67.0 | 9.4 |
| | in FIG. 6 | | | | | | |
| | with a p- | | | | | | |
| | doped Ge | | | | | | |
| | layer | | | | | | |
| 5 | Type shown | 3215.3 | 6.9 | 15.0 | 940 | 66.0 | 9.2 |
| | in FIG. 6 | | | | | | |
| | with a p- | | | | | | |
| | doped Ge | | | | | | |
| | layer | | | | | | |
| 6 | Type shown | 1,430.0 | 7.5 | 13.8 | 953 | 66.0 | 7.9 |
| | in FIG. 6 | | | | | | |
| | with a p- | | | | | | |
| | doped Ge | | | | | | |
| | layer | | | | | | |
| 7 | Type shown | 1,280.4 | 5.7 | 16.9 | 933 | 65.0 | 10.2 |
| | in FIG. 6 | | | | | | |
| | with a p- | | | | | | |
| | doped Si—Ge | | | | | | |
| | alloy layer | | | | | | |

The presence of the germanium-containing layer 22 increased the shunt resistance of photovoltaic device structures of the type shown in FIG. 6 relative to a photovoltaic device having a same material stack less a germanium-containing layer 22, i.e., a photovoltaic device structure that does not include a germanium-containing layer. Further, the presence of the germanium-containing layer 22 decreased the series resistance of photovoltaic device structures of the type shown in FIG. 6 relative to a photovoltaic device having a same material stack less a germanium-containing layer 22, i.e., a photovoltaic device structure that does not include a germanium-containing layer.

The presence of the germanium-containing layer 22 increases the short circuit current density J_{sc} of the photovoltaic device structures of the type shown in FIG. 6 relative to a photovoltaic device having a same material stack less a germanium-containing layer 22. The increase in the short circuit current density J_{sc} causes an increase in the efficiency of the photovoltaic device structures of the type shown in FIG. 6 relative to a photovoltaic device.

The mechanism of the reduction in the series resistance is the modification of the band gap structure in the structure of the present disclosure. The valence band edge of p-doped hydrogenated silicon is about 5.85 eV from the vacuum level. The work-function of ZnO, which is a transpatent conductive oxide, is about 4.5 eV. A barrier height of about 1 eV is present in this case. Amorphous Ge valence band edge is about 5 eV below the vacuum level. Thus, amorphous germanium offers intermediate gap resulting in a barrier height splitting. As the silicon content increases, valence band edge can be located more than 5 eV below the vacuum level. The greater the barrier height, therefore, the greater the benefit of including silicon in germanium so that the Fermi level moves further down from the vacuum level, thereby increasing the shunt resistance.

The germanium-containing layer 22 may, or may not, be doped with p-type dopants. In one embodiment, the germanium-containing layer 22 is a p-doped germanium-containing layer, i.e., includes germanium and at least one p-type dopant atoms such as B, Ga, and In. In another embodiment, the germanium-containing layer 22 is an intrinsic germanium-containing layer, i.e., includes germanium but does not include any p-type dopant atoms. The germanium-containing layer 22 includes hydrogen. Preferably, the germanium-containing layer 22 is a hydrogen-containing amorphous layer, i.e., a layer including amorphous germanium and hydrogen.

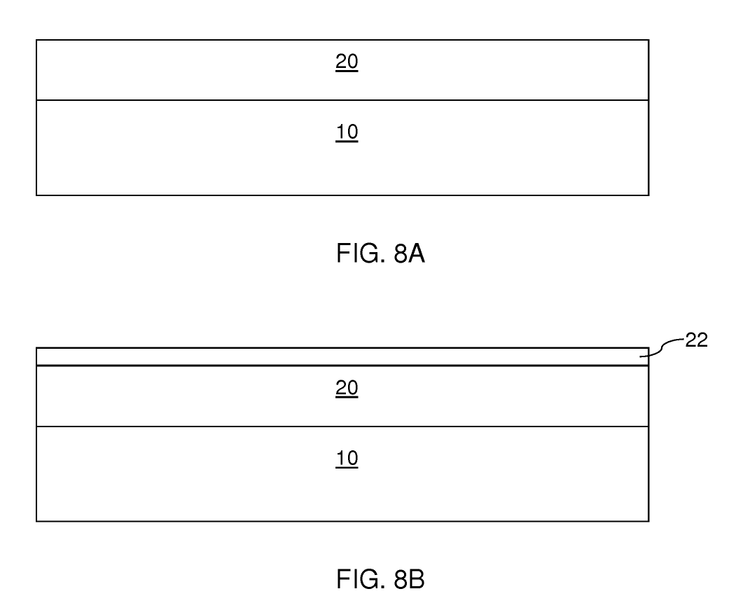

Referring to FIG. 7, a graph compares a first J-V characteristics curve 710 with a second J-V characteristics curve 720. The data in the first J-V characteristic curve 710 was for a stack of a 900 nm-thick zinc oxide as the transparent conductive material layer 20, a 5-nm thick germanium layer as the germanium-containing layer 22, and a 10 nm-thick p-doped silicon layer as the p-doped semiconductor 30 in the exemplary photovoltaic device structure according to an embodiment of the present disclosure. The data in the second J-V characteristic curve 720 was for a stack of a 900 nm-thick zinc oxide as the transparent conductive material layer 20 and a 10 nm-thick p-doped silicon layer as the p-doped semiconductor 30 in the prior art photovoltaic device structure of FIG. 1.

The first J-V characteristics curve 710 shows a series resistance of about 6.0 Ohms-cm², a fill factor of 67%, and an efficiency of about 9.4%. The second J-V characteristics curve 720 shows a series resistance of about 12 Ohms-cm², a fill factor of 57%, and an efficiency of about 8.6%. The presence of a germanium-containing layer provided a ˜10% improvement in the efficiency.

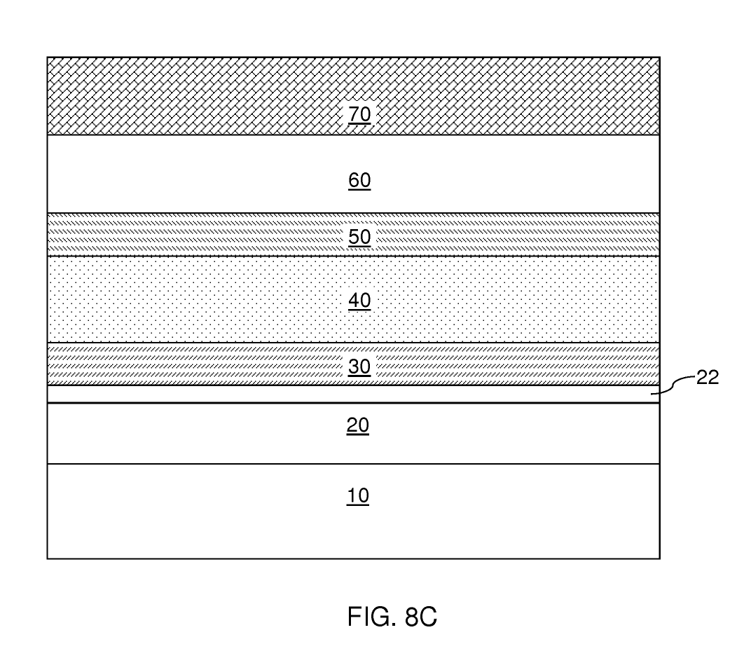

FIG. 8A-8C are sequential vertical cross-sectional views that illustrate a manufacturing process for forming the exemplary photovoltaic device structure of FIG. 6. Referring to FIG. 8A, the substrate 10 includes a material that is transparent in the range of electromagnetic radiation at which photogeneration of electrons and holes occur within the photovoltaic structure as describe above. The transparent conductive material layer 20 is formed on the substrate 10, for example, by deposition.

Referring to FIG. 8B, the germanium-containing layer 22 is deposited for example, by chemical vapor deposition, evaporation, or any other known methods of deposition. The germanium-containing layer 22 can be deposited by plasma enhanced chemical vapor deposition. The germanium-containing layer 22 can be deposited in a process chamber containing a germanium-containing reactant gas and a carrier gas. The germanium-containing layer 22 is formed on a surface of the transparent conductive material layer 20 in the presence of the germanium-containing reactant and the carrier gas in a chemical vapor deposition. In case the carrier gas includes hydrogen, the germanium-containing layer 22 includes a hydrogenated germanium-containing material, which can be germanium or a p-doped silicon-germanium alloy. The atomic concentration of germanium in the germanium-containing layer 22 is greater than 1%, and preferably greater than 10%, and more preferably greater than 30%. The chemical vapor deposition process can be plasma enhanced chemical vapor process (PECVD) performed at a deposition temperature from 50° C. to 400° C., and preferably from 100° C. to 350° C., and at a pressure from 0.1 Ton to 10 Torr, and preferably from 0.2 Torr to 5 Torr.

The germanium-containing reactant gas includes at least one atom of germanium. Exemplary germanium-containing reactant gases include GeH₄, GeH₂Cl₂, GeCl₄, and Ge₂H₆. If the germanium-containing layer 22 includes at least one p-type dopants, the p-type dopants in the p-doped semiconductor-containing material of the germanium-containing layer 22 can be introduced by in-situ doping. Alternately, the p-type dopants in the microcrystalline p-doped hydrogenated semiconductor-containing material can be introduced by subsequent introduction of dopants employing any method known in the art such as plasma doping, ion implantation, and/or outdiffusion from a disposable diffusion source (e.g., borosilicate glass). If the germanium-containing layer 22 includes an intrinsic germanium, no dopant atoms are introduced into the germanium-containing layer 22.

Referring to FIG. 8C, the p-doped semiconductor layer 30 is deposited in a process chamber containing a silicon-containing reactant gas and a carrier gas. The p-doped semiconductor layer 30 is formed on the germanium-containing layer 22 in the presence of the silicon-containing reactant and the carrier gas in a chemical vapor deposition. In case the carrier gas includes hydrogen, the p-doped semiconductor layer 30 includes a hydrogenated p-doped semiconductor material. The chemical vapor deposition process can be plasma enhanced chemical vapor process (PECVD) performed at a deposition temperature from 50° C. to 400° C., and preferably from 100° C. to 350° C., and at a pressure from 0.1 Ton to 10 Torr, and preferably from 0.2 Ton to 5 Torr.

The silicon-containing reactant gas includes at least one atom of silicon. Exemplary silicon-containing reactant gases include SiH₄, SiH₂Cl₂, SiHCl₃, SiCl₄, and Si₂H₆. The p-type dopants in the p-doped semiconductor-containing material of the p-doped semiconductor layer 30 can be introduced by in-situ doping. Alternately, the p-type dopants in the microcrystalline p-doped hydrogenated semiconductor-containing material can be introduced by subsequent introduction of dopants employing any method known in the art such as plasma doping, ion implantation, and/or outdiffusion from a disposable diffusion source (e.g., borosilicate glass).

The material of the p-doped semiconductor layer 30 can be a p-doped hydrogenated silicon-carbon alloy. In this case, a carbon-containing gas can be flown into the processing chamber during deposition of the p-doped hydrogenated silicon-carbon alloy.

Subsequently, the intrinsic semiconductor layer 40 is deposited on the p-doped semiconductor layer 30, for example, by plasma-enhanced chemical vapor deposition. In case the intrinsic semiconductor layer 40 includes an intrinsic hydrogenated semiconductor-containing material, hydrogen gas is supplied into the process chamber concurrently with a semiconductor-material-containing reactant gas. The intrinsic hydrogenated semiconductor-containing material can be amorphous or microcrystalline.

The n-doped semiconductor layer 50 is deposited on the intrinsic semiconductor layer 40, for example, by plasma-enhanced chemical vapor deposition. In case the n-doped semiconductor layer 50 includes an n-doped hydrogenated semiconductor-containing material, hydrogen gas is supplied into the process chamber concurrently with a semiconductor-material-containing reactant gas. The material of the n-doped semiconductor layer 50 can be amorphous or microcrystalline.

The n-type dopants in the n-doped semiconductor layer 50 can be introduced by in-situ doping. For example, phosphine (PH₃) gas or arsine (AsH₃) gas can be flown into the processing chamber concurrently with the semiconductor-material-containing reactant gas if the n-doped semiconductor layer 50 includes an n-doped silicon-containing material or an n-doped germanium-containing material. If the n-doped semiconductor layer 50 includes an n-doped compound semiconductor material, the ratio of the flow rate of the reactant gas for the Group II or Group III material to the flow rate of the reactant gas for the group VI or Group V material can be decreased to induce n-type doping. Alternately, the n-type dopants in the n-doped semiconductor layer 50 can be introduced by subsequent introduction of dopants employing any method known in the art.

The first back reflector layer 60 is deposited on the n-doped semiconductor layer 50 employing methods known in the art. The first back reflector layer 60 includes a transparent conductive material. The second back reflector layer 70 is subsequently deposited on the first back reflector layer 70, for example, by electroplating, electroless plating, physical vapor deposition, chemical vapor deposition, vacuum evaporation, or a combination thereof. The second back reflector layer 70 can be a metallic layer.

While the present disclosure has been particularly shown and described with respect to preferred embodiments thereof, it will be understood by those skilled in the art that the foregoing and other changes in forms and details can be made without departing from the spirit and scope of the present disclosure. It is therefore intended that the present disclosure not be limited to the exact forms and details described and illustrated, but fall within the scope of the appended claims.

What is claimed is:

1. A photovoltaic device comprising a stack of a transparent conductive material layer, a germanium-containing layer contacting said transparent conductive material layer, and a p-doped silicon-containing layer contacting said p-doped silicon-containing layer, wherein said germanium-containing layer has a greater atomic concentration of germanium than said p-doped silicon-containing layer.

2. The photovoltaic device of claim 1, wherein said germanium-containing layer is a germanium layer.

3. The photovoltaic device of claim 2, wherein said germanium-containing layer includes a hydrogenated germanium-containing material.

4. The photovoltaic device of claim 2, wherein said p-doped silicon-containing layer is a p-doped silicon layer.

5. The photovoltaic device of claim 2, wherein said p-doped silicon-containing layer is a p-doped semiconductor material including silicon and germanium.

6. The photovoltaic device of claim 1, wherein said germanium-containing layer includes a p-doped silicon-germanium alloy.

7. The photovoltaic device of claim 6, wherein said germanium-containing layer includes a hydrogenated p-doped silicon-germanium alloy.

8. The photovoltaic device of claim 6, wherein said p-doped silicon-containing layer is a p-doped silicon layer.

9. The photovoltaic device of claim 6, wherein said p-doped silicon-containing layer is a p-doped semiconductor material including silicon and germanium.

10. The photovoltaic device of claim 1, wherein said transparent conductive material layer includes a material selected from an aluminum-doped zinc oxide fluorine-doped and a tin oxide having a fluorine doping.

11. The photovoltaic device of claim 1, wherein said p-doped silicon-containing layer includes a hydrogenated p-doped semiconductor-containing material.

12. The photovoltaic device of claim 1, further comprising:
an intrinsic semiconductor layer contacting said p-doped silicon-containing layer; and
an n-doped semiconductor layer contacting said intrinsic semiconductor layer.

13. The photovoltaic device of claim 12, wherein said intrinsic semiconductor layer includes a hydrogenated amorphous intrinsic semiconductor material.

14. The photovoltaic device of claim 12, wherein said n-doped semiconductor layer includes hydrogenated n-doped amorphous semiconductor material.

15. The photovoltaic device of claim 12, further comprising at least one back reflector layer located on said n-doped semiconductor layer.

16. A method of forming a photovoltaic device comprising:
forming a transparent conductive material layer on a substrate;
forming a germanium-containing layer on said transparent conductive material layer; and
forming a p-doped silicon-containing layer on said germanium-containing layer, wherein said germanium-containing layer has a greater atomic concentration of germanium than said p-doped silicon-containing layer.

17. The method of claim 16, wherein said germanium-containing layer is a germanium layer.

18. The method of claim 17, wherein said germanium-containing layer includes a hydrogenated germanium-containing material.

19. The method of claim 16, wherein said germanium-containing layer includes a p-doped silicon-germanium alloy.

20. The method of claim 16, wherein said transparent conductive material layer includes a material selected from an aluminum-doped zinc oxide fluorine-doped and a tin oxide having a fluorine doping.

21. The method of claim 16, wherein said p-doped silicon-containing layer includes a hydrogenated p-doped semiconductor-containing material.

22. The method of claim 16, further comprising:
an intrinsic semiconductor layer contacting said p-doped silicon-containing layer; and
an n-doped semiconductor layer contacting said intrinsic semiconductor layer.

23. The method of claim 22, wherein said intrinsic semiconductor layer includes a hydrogenated amorphous intrinsic semiconductor material.

24. The method of claim 22, wherein said n-doped semiconductor layer includes hydrogenated n-doped amorphous semiconductor material.

25. The method of claim 22, further comprising at least one back reflector layer located on said n-doped semiconductor layer.
